(19) United States
(12) Patent Application Publication
(10) Pub. No.: US 2020/0117544 A1
(43) Pub. Date: Apr. 16, 2020

(54) DATA BACKUP SYSTEM AND DATA BACKUP METHOD

(71) Applicant: INSTITUTE FOR INFORMATION INDUSTRY, TAIPEI (TW)

(72) Inventors: Shih-Yu LU, Nantou County (TW); Chih-Hsuan LIANG, New Taipei City (TW); Chao-Chin YANG, Taoyuan City (TW)

(21) Appl. No.: 16/194,398

(22) Filed: Nov. 19, 2018

(30) Foreign Application Priority Data
Oct. 12, 2018 (TW) 107136082

(51) Int. Cl. G06F 11/14; H03M 7/30

(52) U.S. Cl. CPC G06F 11/1451; H03M 7/3084; G06F 11/1464

(57) ABSTRACT

The disclosure provides a data backup system. The data backup system comprises an electronic device and a server. The electronic device is configured to store original data. The server predicts a data size of predicted compressing data and a first predicted compressing time corresponding to the predicted compressing data, which are generated by compressing the original data with a plurality of compressing algorithm respectively. The server fetches a computing resource data of the electronic device and predicts respectively a plurality of second predicted compressing time for which the electronic device compresses the original data according to the computing resource data and the plurality of first predicted compressing time. The server computes a plurality of reference data and generates a recommending command according to a default compressing algorithm of the plurality of the compressing algorithm which corresponds to the minimal reference data.

CROSS-REFERENCE TO RELATED APPLICATION

This application claims priority to Taiwan Application Serial Number 107136082, filed on Oct. 12, 2018, which is herein incorporated by reference.

### BACKGROUND

### Field of Disclosure

The disclosure relates to a data system and method. More particularly, the disclosure relates to a data backup system and method.

### Description of Related Art

With the development of Internet of Things (IoT) technology, the amount of terminals devices in the internet grows such that the transmitting data size becomes enormous. To save the cost, the data compression technology will be applied before the terminal device transmits data, in order to decrease the transmitting data size and save the network bandwidth.

However, the data compression computing procedure is performed by the remote device. If the data size that the terminal device need to compress the data is large, the burden of the remote device is high. Therefore, there is a problem how to decrease the service burden of the remote device.

Therefore, the present disclosure provides the system and method to recommend data compression algorithm based on the system status of the remote device and the data type. Further, the system and method take the sampling data to obtain the compressing time and the data size and related message, in order to predict the backup time for compressing. Accordingly, the system and method recommend the most suitable data compressing algorithm without analyzing the data or the data type.

### SUMMARY

The disclosure provides a data backup system. The data backup system includes an electronic device and a server. The electronic device includes a storage media. The storage media is configured to store an original data. The server configured to communicate with the electronic device. The server predicts a compression of the original data that is compressed respectively by each of a plurality of compression algorithms, and obtains a data size of a predicted compressing data and a first predicted compressing time corresponding to the predicted compressing data. The server retrieves a computing resource data of the electronic device, and predicts a plurality of second predicted compressing time respectively that the electronic device compresses the original data according to the computing resource data and the first predicted compressing time server. The server estimates a first adding data generating in each of the plurality of second predicted compressing time, and sums up the data size of the predicted compressing data and the data size of the first adding data respectively to obtain a plurality of reference values. The server generates a recommend instruction, according to a default compression algorithm of the plurality of compression algorithms that the default compression algorithm corresponds to the smallest reference values, to provide the electronic device to back up data using the default compression algorithm by the recommend instruction.

The disclosure provides a data backup method. The data backup method includes the steps: predicting, by a server, a compression of an original data that is compressed respectively by each of a plurality of compression algorithms, and obtaining a data size of a predicted compressing data and a first predicted compressing time corresponding to the predicted compressing data, wherein the original data is stored in an electronic device communicating with the server; predicting respectively, by the server, a plurality of second predicted compressing time that the electronic device compresses the original data according to a computing resource data of the electronic device and the first predicted compressing time; estimating a first adding data obtained during each of the plurality of second predicted compressing time; obtaining a plurality of reference values by summing up the data size of the predicted compressing data and the data size of the first adding data respectively; determining the smallest reference value corresponding to a default compression algorithm of the plurality of compression algorithm, to generate a recommend instruction; and using, by the electronic device, the default compression algorithm to back up data according to the recommend instruction.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a functional block diagram illustrating a data backup system according to an embodiment of the disclosure.

FIG. 2 is a flow diagram illustrating a data backup method according to an embodiment of the disclosure.

FIG. 3 is a schematic diagram illustrating a data growth curve according to an embodiment of the disclosure.

FIG. 4 is a schematic diagram illustrating a time growth curve according to an embodiment of the disclosure.

FIG. 5 is a schematic diagram illustrating a computing performance curve according to an embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

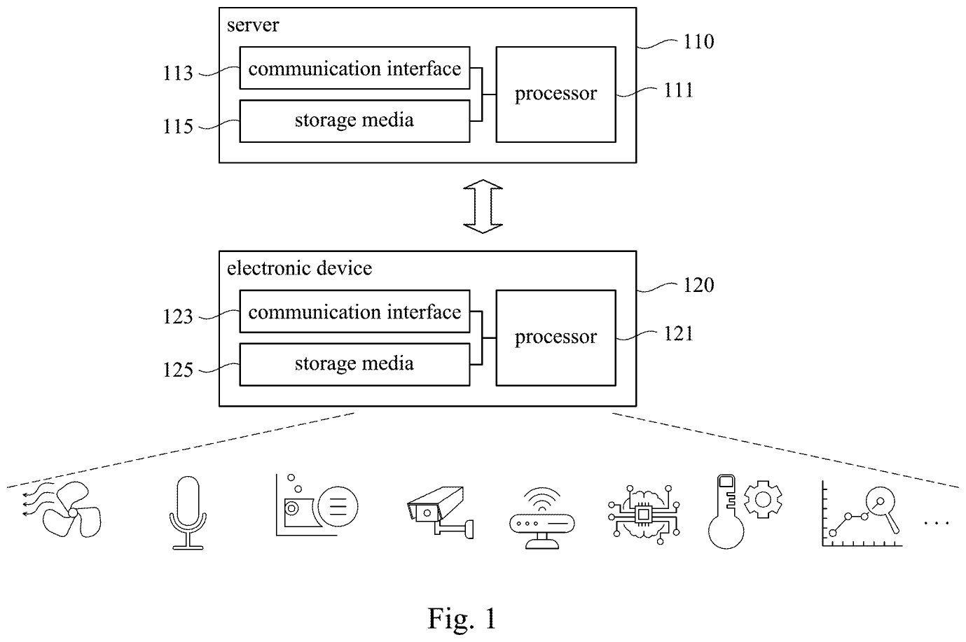

FIG. 1 is a functional block diagram illustrating a data backup system according to an embodiment of the disclosure. The data backup system includes a server 110 and an electronic device 120. In an embodiment, the data backup system includes at least one electronic device 120. In the data backup system, the server 110 communicates with the at least one electronic device 120.

The server 110 includes a processor 111, a communication interface 113 and a storage media 115. The processor 111 is coupled to the communication interface 113 and the storage media 115. The electronic device 120 includes a processor 121, a communication interface 113 and a storage media 115. The processor 121 is coupled to the communication interface 123 and the storage media 125.

When a data of the electronic device 120 needs to be backed up, the electronic device 120 transmits the data to the server 110. After storing the data, the server 110 feedbacks an message to the electronic device 120 to inform that the backup procedure is completed. In one embodiment, before the electronic device 120 performs the backup procedure, the server 110 provides a suitable compression algorithm to the electronic device 120 according to the current status of the electronic device 120. The electronic device 120 is but not limited to a mobile device, an IoT (Internet of Things) device, a Fog Computing device, etc.

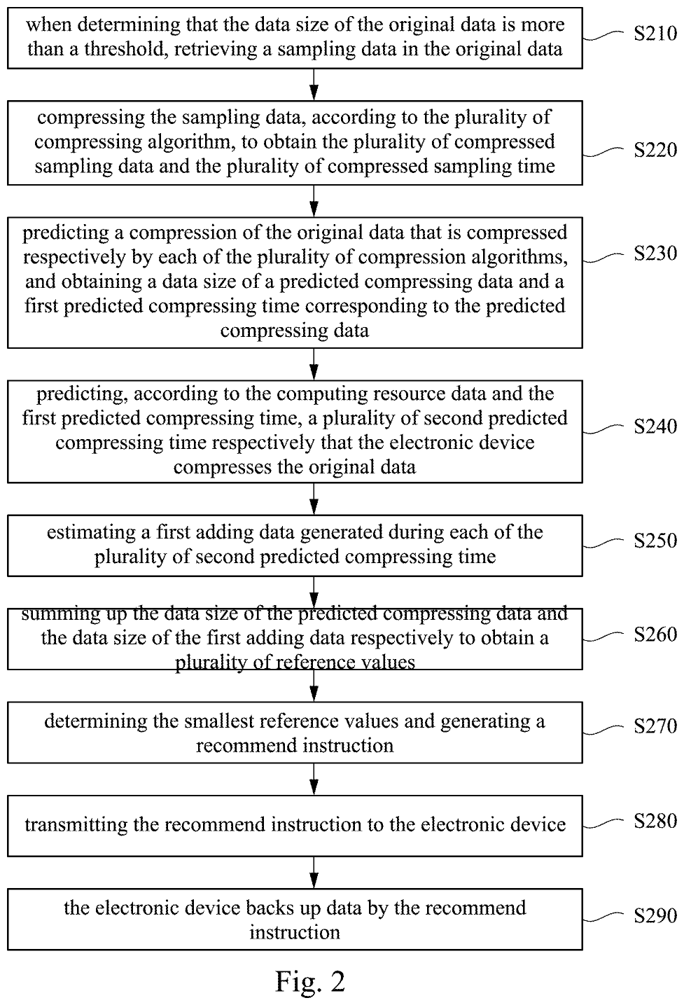

FIG. 2 is a flow diagram illustrating a data backup method according to an embodiment of the disclosure. Please refer to FIG. 1 and FIG. 2. In the data backup system, the processor 121 of the electronic device 120 controls a data size of the storage media 125. In general, the data generated by elements of the electronic device 120 (such as data generated by sensors (not shown)), or the data received by the electronic device 120 from other terminal device (such as audio data, video data, etc.), is stored in the storage media 125 of the electronic device 120 with an original data format. To manage the storage space of the electronic device 120, the electronic device 120 determines whether a data size of an original data is more than a threshold value (such as 70% storage space of the storage media 125). If the data size of the original data is more than the threshold value, processor 121 will retrieve a sampling data from the original data, which the data size of the sampling data is less than the data size of the original data. For example, the data size of the original data is 5 GB (Gigabytes), the data size of the sampling data is 2 MB (Megabytes). The sampling data is transmitted to the server 110 through the communication interface 123. In one embodiment, the sampling data will be transformed to a bit stream before being transmitted.

The processor 111 of the server 110 can compress data by using different compression algorithms. The compression algorithms can be but not limited to Lempel-Ziv-Storer-Szymanski (LZSS) data compressing algorithm, ZIP data compressing algorithm, TGZ data compressing algorithm, Lempel-Ziv-Welch (LZW) data compressing algorithm, etc. After the server 110 receives the original data, in step S220, the processor 111 compresses the sampling data according to the plurality of compression algorithms respectively to obtain a plurality of compressed sampling data and a plurality of compressed sampling times. Take the LZSS compression algorithm as example. The processor 111 compresses the sampling data which data size is 2 MB, and the processor 112 costs 2 seconds to generate the compressed sampling data which data size is 300 KB. The processor 111 records the data size of 300 KB and the compressed sampling time of 2 seconds. Similarly, the processor 111 compresses, using the ZIP compression algorithm, the sampling data which data size is 2 MB. The processor 111 costs 2.2 seconds generating the compressing data which data size is 320 KB. Therefore, the server 110 can obtain a plurality of data size of the compresses sampling data and a plurality of compressed sampling time corresponding to each one of the plurality of compression algorithms.

After retrieving compressing-related information about the sampling data, the server 110 can estimate a compressing time and a data size of a compressed data in response to compressing the original data. In step S230, the processor 111 of the server 110 estimates the data size of a plurality of predicted compressing data and a plurality of first compressing time when the original data is compressed by the plurality of compression algorithms respectively. The server 110 can obtain the data size of the predicted compressing data and the first compressing time by a data-compression estimating model created in advance. For example, the method for establish the data-compression estimating model includes collecting multiple data, retrieving a data segment with different data size among the multiple data, and compressing the data segment, by using different data compression algorithms. After compressing, the server 110 records the data size of the compressed data segment and the compressing time to compress the data segment respectively. Then, the server 110 computes liner regression about the data size of the compressed data segment to obtain a data growth curve according to the data size of the data segment and the data size of the compressed data segment.

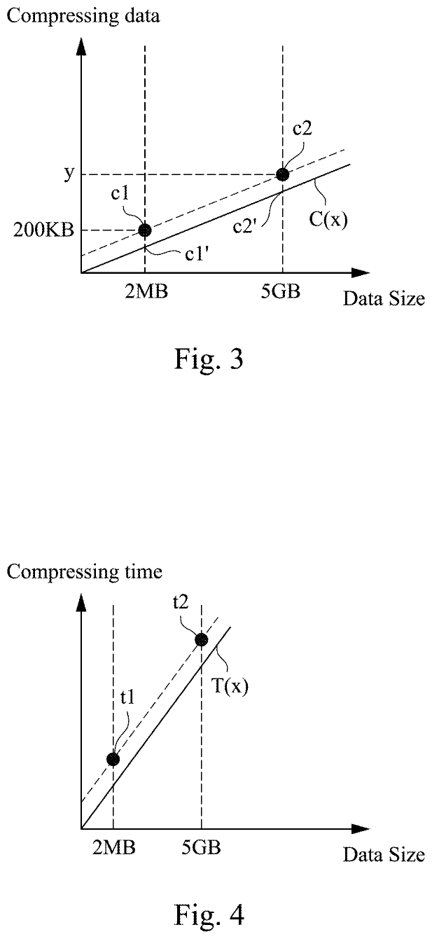

FIG. 3 is a schematic diagram illustrating a data growth curve according to an embodiment of the disclosure. As shown in FIG. 3, the horizontal axis of the coordinate is the data size, the vertical axis of the coordinate is the data size after compressing. The data growth curve C(x) is the curve obtained from linear regression. Each data compression algorithm corresponds to their data growth curve C(x), and FIG. 3 takes LZSS compression algorithm as an example. The data listed in table 1 are derived by the method that each compression algorithm is executed and the values can be obtained by calculating the linear regression of the compressing data. The present disclosure can use other data compression algorithm to obtain values. The table 1 takes LZSS algorithm and ZIP algorithm as examples.

TABLE 1

| data compression | | | | | | |
|---|---|---|---|---|---|---|
| algorithm | 100 KB | 1 MB | 10 MB | | 5 GB | . . . |
| LZSS | 20 KB | 220 KB | 2 | MB | 1.1 GB | . . . |
| ZIP | 30 KB | 314 KB | 2.8 | MB | 1.6 GB | . . . |

The server 110 predicts the data size that the original data is compressed by using the data growth curve C(x). In one embodiment, point c1′ and point c2′ in the data growth curve C(x) and the coordinate of point c1′ is (2 MB, 100 KB), and the coordinate of the point c2′ is (5 GB, 250 MB). The server 110 compresses the sampling data with the data size, 2 MB, and obtains the compressed data with data size, 200 KB. That is, the coordinate of point c1 in FIG. 3 is (2 MB, 200 KB). Based on the same data compression rate, the larger the data size to compress is, the larger the data size of the compressing data is. Therefore, the slope of the data growth curve C(x) is close to the slope of the curve of real sample points. After retrieving the point c1, the server 110 can calculate the y value of the point c2 according to the slope of the data growth curve C(x) and the coordinate of point c1. The formula is as following:

$$\frac{250 Mb - 100 KB}{5 GB - 2 MB} = \frac{y - 150 KB}{5 GB - 2 MB}$$

Hence, the result value y is a predicted data size that the original data is compressed.

Similarly, the time growth curve can be obtained by computing the linear regression of the data size and the corresponding compressing time. FIG. 4 is a schematic diagram illustrating a time growth curve according to an embodiment of the disclosure. With the same reason as above, the slope of the time growth curve T(x) will be close to the slope of line composed of the actual sampled points. After retrieving the point t1, the server 110 can compute the y value of the point t2 according to the slope of the time growth curve T(x) and the coordinate of point t1, to obtain a predicted compressing time that the original data is compresses. The data listed in Table 2 are derived by the method that each compression algorithm is executed and the compressing time is obtained by calculating the linear regression of the compressing time. The present disclosure can use other data compression algorithm to obtain the values. The table 2 takes LZSS algorithm and ZIP algorithm as examples.

TABLE 2

| Compressing | | | | | | |
|---|---|---|---|---|---|---|
| methods | 100 KB | | 1 MB | 10 MB | 5 GB | . . . |
| LZSS | 1 | second | 8 seconds | 49 seconds | . . . | . . . |
| ZIP | 0.9 | second | 7 seconds | 41 seconds | . . . | . . . |

It should be noted that, the predicted compressing time for the original data is the predicted time that the server 110 needs to compress the original data. Because the computation ability of the electronic device 120 may not be the same with that of the server 110 (usually, the computation ability of the electronic device 120 is worse) and the computation ability of the electronic device 120 also cannot maintain at the state of 100% usage, the predicted compressing time should be adjusted.

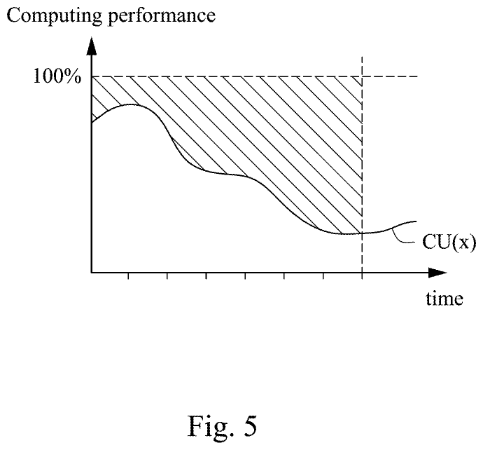

Please refer back to FIG. 2, in step S240, the server 110, according to a computing resource data of the electronic device 120 and the first predicted compressing time, predicts a plurality of second predicted compressing time respectively that the electronic device 120 needs to compress the original data. FIG. 5 is a schematic diagram illustrating a computing performance curve according to an embodiment of the disclosure. The server 110 receives periodically a client state data of the electronic device 120, and trains a computing resource model according to the client state data (such as a processor performance data). In one embodiment, a computing performance curve CU(x) is the curve obtained from computing training, to indicate the percentage of the computing performance of the electronic device 120 at any time point in the future. Because the area below the computing performance curve CU(x) is the predicated performance that the electronic device 120 is busy at some other tasks. Therefore, the present disclosure provides to compute the area between the computing performance curve CU(x) and 100% computing performance, as an available computing resource of the electronic device 120 for data compression, as the slash area shown in FIG. 5. In one embodiment, the method for training computing resource model can be but not limited to use the Support Vector Regression (SVR) algorithm to build the model.

In one embodiment, supposing that the processor 111 of the server 110 uses 100% of the computing resource to compress the original data and the predicted compressing time is 3 minutes, it means that the total resource needed by processor 111 to compress the original data is 100×3. Then, the present disclosure converts the total resource into the compressing time needed by the electronic device 120, the formula is shown as following:

100×3≤[(100−80)×1]+[(100−70)×1]+[(100−50)×1]+[(100−50)×1]+[(100−40)×1]+[(100−30)×1]+[(100−30)×1]=350

In the formula above, there are 20 available computing resources in the first minute, there are 30 available computing resources in the second minute, and there are 50 total available computing resources, and so on. In the seventh minute, there are 350 total available computing resources. Because the processor 111 demands 300 of the computing resource, the requirement should be more than 300 of the computing resources. Hence, the conversion result is that the electronic device 120 needs 7 minutes to complete the compression of the original data. It should be noted that the server 110 will, according to all the compression algorithm, converts a first predicted compressing time needed by the server 110 to perform compression into a second predicted compressing time needed by the electronic device 120. The above formula takes LSZZ compression algorithm as example. The server 110 can perform different data compression algorithm to obtain different first predicted compressing time. Hence, the length of time will be different from the algorithm when converting the first predicted compressing time into the second predicted compressing time needed by the electronic device 120.

Then, in step S250, the server 110 predicts a first adding data generating in each of the plurality of second predicted compressing time. For example, it takes time to perform data compression by the electronic device 120, therefore, there may be new data received during the compression process. The new data is, for example, the data generated continuously by sensors of the electronic device 120. Because the usage of the storage media 125 of the electronic device 120 is more than threshold value, it should be assessed that whether the data size of total usage is more than the storage space of the storage media 125 while the electronic device 120 executes the compressing data process.

In step S260, the server 110 sums up, according to each of the plurality of data compression algorithm respectively, the data size of the predicted compressing data and the data size of the first adding data, to obtain a plurality of reference values. For example, in the time of 7 minutes, the storage media 125 of the electronic device 120 stores not only the compressed original data but also new data adding in 7 minutes. Then, in step S270, the server 110 generates a recommend instruction by determining the smallest one among the reference values. The present disclosure provides the most suitable data compression algorithm for the electronic device 120 to use, the recommend instruction is used for indicating the data compression algorithm that the electronic device 120 should use. On the other hand, if the reference value (i.e. total data size) is more than the storage space of the storage media 125, it means that if the electronic device 120 uses the data compression algorithm, it will lead to lack of storage space. Hence, the corresponding data compression algorithm can be eliminated.

In step S280, the server 110 transmits the recommend instruction to the electronic device 120. In step S290, the electronic device 120 backs up data according to the recommend instruction. For example, the electronic device 120 uses the compression algorithm indicated by the recommend instruction to compress the original data, to generate the compressing data. The compressing data is stored in the storage media 125. Then, the compressing data is transmitted to the storage media 115 of the server 110 through the communication interface 123. After receiving the acknowledgement of the data transmitting, the original data stored in the storage media 125 of the electronic device 120 will be deleted. Therefore, the data backup procedure is completed.

In another embodiment, the present disclosure considers the procedure that the electronic device 120 executes the data backup, that is, the procedure that the compressing data is transmitted to the server 110, the electronic device 120 may receive or generate a second adding data. Hence, the present disclosure also predicts the data transmitting time according to a data transmission rate of the electronic device 120. For example, the predicted data transmitting time can be estimated by dividing the second adding data by the data transmission rate.

In the embodiment, the server 110 can obtain the plurality of reference values by summing up the data size of the original data, the data size of the compressed original data, the data size of the first adding data, and the data size of the second adding data corresponding to each one of the plurality of compression algorithm. By determining the smallest one among the reference values to generate the recommend instruction, and the recommend instruction can be provided to the electronic device 120 to back up data. On the other hand, if the finally retrieved reference value (i.e. total data size) is more than the storage space of the storage media 125, it means that if the electronic device 120 uses the data compression algorithm, it will lead to lack of storage space. Hence, the corresponding data compression algorithm can be eliminated.

In one embodiment, the electronic device 120 will check whether it can execute the data compression algorithm indicated by the recommend instruction. If the electronic device 120 determines that it cannot execute the data compression algorithm, the electronic device 120 requests the server 110 for the data compression algorithm.

As mentioned above, the data backup system and the data backup method in the present disclosure can provide the most suitable for the electronic device 120 to perform the data compression algorithm without analyzing the data type. On the other hand, due to the limited storage space of the electronic device 120, the compressed data should not cost too much resource to be stored. Hence, the data backup system and the data backup method of the present disclosure provide that the electronic device 120 backs up data by using the most suitable compression algorithm. The problem that the backup process is forced to interrupt or fail due to lack of storage space during backup process can be also solved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A data backup system comprising:
an electronic device, comprising a storage media, wherein the storage media is configured to store an original data; and
a server configured to communicate with the electronic device, the server to predict a compression of the original data that is compressed respectively by each of a plurality of compression algorithms, and obtain a data size of a predicted compressing data and a first predicted compressing time corresponding to the predicted compressing data, wherein the server retrieves a computing resource data of the electronic device and predicts, according to the computing resource data and the first predicted compressing time, a plurality of second predicted compressing time respectively that the electronic device compresses the original data;
wherein the server estimates a first adding data obtained during each of the plurality of second predicted compressing time, and sums up respectively the data size of the predicted compressing data and the data size of the first adding data to obtain a plurality of reference values, wherein the server generates a recommend instruction, according to a default compression algorithm of the plurality of compression algorithms that the default compression algorithm corresponds to the smallest reference values, to provide the recommend instruction to the electronic device to back up data using the default compression algorithm according to the recommend instruction.

2. The data backup system of claim 1, wherein when the electronic device determines that the data size of the original data is more than a threshold value, the electronic device retrieves a sampling data from the original data, and the server compresses the sampling data, according to the plurality of compression algorithms respectively, to obtain a plurality of compressed sampling data and a plurality of compressed sampling time corresponding to the plurality of the compressed sampling data.

3. The data backup system of claim 2, wherein the server predicts, by using a data growth curve corresponding to the plurality of compression algorithm and the data size of the compressed sampling data, the predicted compressing data that the server compresses the original data; and
the server predicts, by using a time growth curve corresponding to the plurality of compression algorithms and the compressed sampling time, the first predicted compressing time that the server compresses the original data.

4. The data backup system of claim 3, wherein the server is further configured to compute a data transmitting time according to the data size of the predicted compressing data and a data transmission rate of the electronic device; and
the server obtains the plurality of reference value, by summing up respectively the data size of the original data, the data size of the predicted compressing data, the data size of the first adding data, and the data size of a second adding data in the data transmitting time, to obtain the plurality of reference values, and the server generates the recommend instruction according to the smallest one among the plurality of reference values.

5. The data backup system of claim 4, wherein the electronic device receives the recommend instruction and compresses the original data according to one of the plurality of compression algorithm indicated by the recommend instruction, to generate a compressing data, and the compressing data is stored in the storage media; and
the electronic device transmits the compressing data to the server and deletes the original data in the storage media.

6. A data backup method comprising:
predicting, by a server, a compression of an original data that is compressed respectively by each of a plurality of compression algorithms, and obtaining a data size of a predicted compressing data and a first predicted compressing time corresponding to the predicted compressing data, wherein the original data is stored in an electronic device that communicates with the server;
predicting respectively, by the server, a plurality of second predicted compressing time that the electronic device compresses the original data according to a computing resource data of the electronic device and the first predicted compressing time;
estimating a first adding data obtained during each of the plurality of second predicted compressing time;
obtaining a plurality of reference values by summing up respectively the data size of the predicted compressing data and the data size of the first adding data;
determining the smallest reference value corresponding to a default compression algorithm of the plurality of compression algorithm, to generate a recommend instruction; and
using, by the electronic device, the default compression algorithm to back up data according to the recommend instruction.

7. The data backup method of claim 6, further comprising:
retrieving a sampling data from the original data when determining, by the electronic device, that the data size of the original data is more than a threshold value; and
compressing, by the server, the sampling data according to the plurality of compression algorithm respectively, to obtain a plurality of compressed sampling data and a plurality of compressed sampling time corresponding to the plurality of the compressed sampling data.

8. The data backup method of claim 7, further comprising:
predicting, by using a data growth curve corresponding to the plurality of compression algorithm and the data size of the compressed sampling data, the predicted compressing data that the server compresses the original data; and
predicting, by using a time growth curve corresponding to the plurality of compression algorithms and the compressed sampling time, the first predicted compressing time that the server compresses the original data.

9. The data backup method of claim 8, further comprising:
computing a data transmitting time according to the data size of the predicted compressing data and a data transmission rate of the electronic device;
obtaining the plurality of reference values, by summing up respectively the data size of the original data, the data size of the predicted compressing data, the data size of the first adding data, and the data size of a second adding data in the data transmitting time; and
generating the recommend instruction according to the smallest one among the plurality of reference values.

10. The data backup method of claim 9, further comprising:
receiving the recommend instruction by the electronic device, and compressing the original data to generate a compressing data according to one of the plurality of compression algorithms indicated by the recommend instruction;
storing the compressing data in a storage media of the electronic device; and
transmitting, by the electronic device, the compressing data to the server and deleting the original data in the storage media.
